(19) United States
(12) Patent Application Publication
(10) Pub. No.: US 2025/0380470 A1
(43) Pub. Date: Dec. 11, 2025

(54) SEMICONDUCTOR DEVICE

(71) Applicant: TOYODA GOSEI CO., LTD., Kiyosu-shi (JP)

(72) Inventors: Go NISHIO, Kiyosu-shi (JP); Takaki NIWA, Kiyosu-shi (JP)

(21) Appl. No.: 19/225,584

(22) Filed: Jun. 2, 2025

(30) Foreign Application Priority Data
Jun. 11, 2024 (JP) 2024-094424

(51) Int. Cl. H10D 62/10; H10D 30/01; H10D 30/66; H10D 62/00

(52) U.S. Cl. CPC H10D 62/109; H10D 30/0297; H10D 30/668; H10D 62/058

(57) ABSTRACT

A semiconductor device includes: a substrate; a main drift layer provided over the substrate; a current dispersion layer provided over the main drift layer; a sub-drift layer provided over the current dispersion layer; a second conductivity type blocking layer provided in contact with the sub-drift layer, and having a groove; a second conductivity type body layer provided over the sub-drift layer and the second conductivity type blocking layer; a high concentration first conductivity type impurity-containing layer provided over the second conductivity type body layer; a gate trench in a groove shape extending from the high concentration first conductivity type impurity-containing layer to at least the sub-drift layer; a gate insulating film; and a gate electrode as defined herein, and a bottom portion of the gate trench is located closer to the high concentration first conductivity type impurity-containing layer than a bottom surface of the second conductivity type blocking layer.

### CROSS-REFERENCE TO RELATED APPLICATION

This application is based on and claims priority under 35 USC 119 from Japanese Patent Application No. 2024-094424 filed on Jun. 11, 2024.

### TECHNICAL FIELD

The present invention relates to a semiconductor device.

### BACKGROUND ART

In a semiconductor device having a gate trench structure, in an off state in which a gate voltage is less than a threshold value, a leakage current is likely to be generated due to electrolysis concentration on a bottom portion of a gate trench, and thus a breakdown voltage tends to be low. Therefore, in configurations disclosed in Patent Literature 1 and Patent Literature 2, a p blocking layer is provided between a p body layer and an n-drift layer to alleviate electrolysis concentration on a bottom portion of a gate trench and to prevent current leakage, thereby improving a breakdown voltage. Further, in the configuration disclosed in Patent Literature 1, an n current dispersion layer is provided from the gate trench to a region below the p blocking layer to sufficiently disperse the current to the n-drift layer, so that a large amount of current is likely to flow in an on-state in which a gate voltage is equal to or greater than a threshold value to reduce on-resistance. In addition, in the configuration disclosed in Patent Literature 2, an n current dispersion layer is provided in a region excluding a region below the p blocking layer to reduce the on-resistance.
Patent Literature 1: JP2020-512682A
Patent Literature 2: JP2019-054174A

### SUMMARY OF INVENTION

However, in the configuration disclosed in Patent Literature 1, since an electric field strength of a corner portion on the bottom portion of the gate trench or a corner portion of the p blocking layer on a trench side increases, the leakage current increases, and the breakdown voltage decreases. In addition, in the configuration disclosed in Patent Literature 2, since the n current dispersion layer is not provided below the p blocking layer, an effect of reducing the on-resistance is not sufficient. Therefore, in a semiconductor device having a gate trench structure, there is a room for improvement in achieving both an improvement in breakdown voltage and a reduction in on-resistance.

The present invention has been made in view of such a background, and an object of the present invention is to provide a semiconductor device capable of achieving both an improvement in breakdown voltage and a reduction in on-resistance.

An aspect of the present invention provides a semiconductor device including:
a substrate made of a semiconductor containing a first conductivity type impurity;
a main drift layer provided on the substrate and containing a first conductivity type impurity at a lower concentration than the substrate;
a current dispersion layer provided on the main drift layer and containing a first conductivity type impurity at a lower concentration than the substrate and at a higher concentration than the main drift layer;
a sub-drift layer provided on the current dispersion layer and containing a first conductivity type impurity at a lower concentration than the current dispersion layer;
a second conductivity type blocking layer containing a second conductivity type impurity, provided in contact with the sub-drift layer, and having a groove formed therein;
a second conductivity type body layer provided on the sub-drift layer and the second conductivity type blocking layer, and containing a second conductivity type impurity at a same concentration as the second conductivity type blocking layer or at a lower concentration than the second conductivity type blocking layer;
a high concentration first conductivity type impurity-containing layer provided on the second conductivity type body layer and containing a first conductivity type impurity at a higher concentration than the current dispersion layer;
a gate trench formed in a groove shape extending from the high concentration first conductivity type impurity-containing layer to at least the sub-drift layer;
a gate insulating film provided in a film shape along a bottom surface and a side surface of the gate trench; and
a gate electrode provided in a film shape along the bottom surface and the side surface of the gate trench via the gate insulating film, in which
a bottom portion of the gate trench is located closer to the high concentration first conductivity type impurity-containing layer than a bottom surface of the second conductivity type blocking layer.

In the above aspect, the sub-drift layer is provided on the current dispersion layer formed on the main drift layer, and the second conductivity type blocking layer having the groove is provided in contact with the sub-drift layer. Then, the gate trench is formed in a groove shape reaching at least the sub-drift layer, and the bottom portion of the gate trench is located closer to the high concentration first conductivity type impurity-containing layer than the bottom surface of the second conductivity type blocking layer. Accordingly, since a wide current flow path in the current dispersion layer can be ensured, it is possible to make it easier for a large amount of current to flow in an on-state and to reduce on-resistance. Further, with the above configuration, the second conductivity type blocking layer can prevent an increase in electric field strength at a corner portion on the bottom portion of the gate trench or a corner portion of the second conductivity type blocking layer on a trench side, and a leakage current is less likely to flow, thereby improving a breakdown voltage. Therefore, it is possible to achieve both an improvement in breakdown voltage and a reduction in on-resistance.

As described above, in the above aspect, it is possible to provide a semiconductor device capable of achieving both an improvement in breakdown voltage and a reduction in on-resistance.

### BRIEF DESCRIPTION OF DRAWINGS

FIG. 1 is a cross-sectional view showing a configuration of a semiconductor device according to a first embodiment, which is a cross-sectional view perpendicular to a substrate main surface.

FIG. 2 is a diagram showing an example of a plane pattern of trenches.

FIG. 3 is a diagram showing another example of the plane pattern of the trenches.

FIG. 4 is a diagram showing a step of producing the semiconductor device according to the first embodiment.

FIG. 5 is a diagram showing a step of producing the semiconductor device according to the first embodiment.

FIG. 6 is a diagram showing a step of producing the semiconductor device according to the first embodiment.

FIG. 7 is a diagram showing a step of producing the semiconductor device according to the first embodiment.

FIG. 8 is a diagram showing a step of producing the semiconductor device according to the first embodiment.

FIG. 9 is a diagram showing a step of producing the semiconductor device according to the first embodiment.

FIG. 10 is a diagram showing a step of producing the semiconductor device according to the first embodiment.

FIG. 11 is a diagram showing a step of producing the semiconductor device according to the first embodiment.

FIG. 12 is a diagram showing a step of producing the semiconductor device according to the first embodiment.

FIG. 13 is a cross-sectional view showing a configuration of a semiconductor device according to a first modification, which is a cross-sectional view perpendicular to a substrate main surface.

FIG. 14 is a cross-sectional view showing a configuration of a semiconductor device according to a second modification, which is a cross-sectional view perpendicular to a substrate main surface.

FIG. 15 is a cross-sectional view showing a configuration of a semiconductor device according to a third modification, which is a cross-sectional view perpendicular to a substrate main surface.

FIG. 16 is a cross-sectional view showing a configuration of a semiconductor device according to a second embodiment, which is a cross-sectional view perpendicular to a substrate main surface.

FIG. 17 is a diagram showing a step of producing the semiconductor device according to the second embodiment.

FIG. 18 is a diagram showing a step of producing the semiconductor device according to the second embodiment.

FIG. 19 is a cross-sectional view showing a configuration of a semiconductor device according to a fourth modification, which is a cross-sectional view perpendicular to a substrate main surface.

FIG. 20 is a cross-sectional view showing a configuration of a semiconductor device according to a fifth modification, which is a cross-sectional view perpendicular to a substrate main surface.

### DESCRIPTION OF EMBODIMENTS

The current dispersion layer may include a first current dispersion layer in contact with the main drift layer, and a second current dispersion layer covering a wall surface of the groove in the second conductivity type blocking layer, and the sub-drift layer may include a first sub-drift layer in contact with the first current dispersion layer and the second conductivity type blocking layer, and a second sub-drift layer in contact with the second current dispersion layer and the gate insulating film. In this case, while the on-resistance is further reduced by the second current dispersion layer, the generation of the leakage current can be further prevented by the first and second sub-drift layers and the first and second current dispersion layers to improve the breakdown voltage.

The second current dispersion layer may be disposed so as not to be in contact with a corner portion on the bottom portion of the gate trench. In this case, an increase in electric field strength at the corner portion on the bottom portion of the gate trench can be prevented to improve the breakdown voltage.

The first current dispersion layer and the second current dispersion layer may be in contact with each other. In this case, a current dispersion effect is promoted, and the on-resistance can be further reduced.

The second sub-drift layer may be in contact with an entire lower surface of the second conductivity type body layer, and the second current dispersion layer may be in contact with an entire lower surface of the second sub-drift layer. In this case, the current dispersion effect is promoted, and the on-resistance can be further reduced.

The first sub-drift layer may be interposed between the first current dispersion layer and the second current dispersion layer. In this case, even when the first current dispersion layer and the second current dispersion layer are separated from each other, the effect of reducing the on-resistance can also be obtained, and the generation of the leakage current can also be prevented to improve the breakdown voltage.

A portion of the second current dispersion layer may enter the first current dispersion layer. In this case, since a contact area between the first current dispersion layer and the second current dispersion layer increases, the current dispersion effect can be promoted to further reduce the on-resistance, and the generation of the leakage current can be prevented to improve the breakdown voltage.

The bottom portion of the gate trench may enter the groove in the second conductivity type blocking layer, and the second sub-drift layer may be interposed between the bottom portion of the gate trench and the second current dispersion layer. In this case, the generation of the leakage current can be prevented to improve the breakdown voltage.

The bottom portion of the gate trench may include a portion entering the groove in the second conductivity type blocking layer and a portion located inside the second conductivity type blocking layer, and a corner portion on the bottom portion of the gate trench may be not in contact with the second current dispersion layer. In this case, the generation of the leakage current can be prevented to improve the breakdown voltage.

The entire bottom portion of the gate trench may be located inside the second conductivity type blocking layer, and a corner portion on the bottom portion of the gate trench may be not in contact with the second current dispersion layer. In this case, the generation of the leakage current can be prevented to improve the breakdown voltage.

### First Embodiment

### 1. Configuration of Semiconductor Device

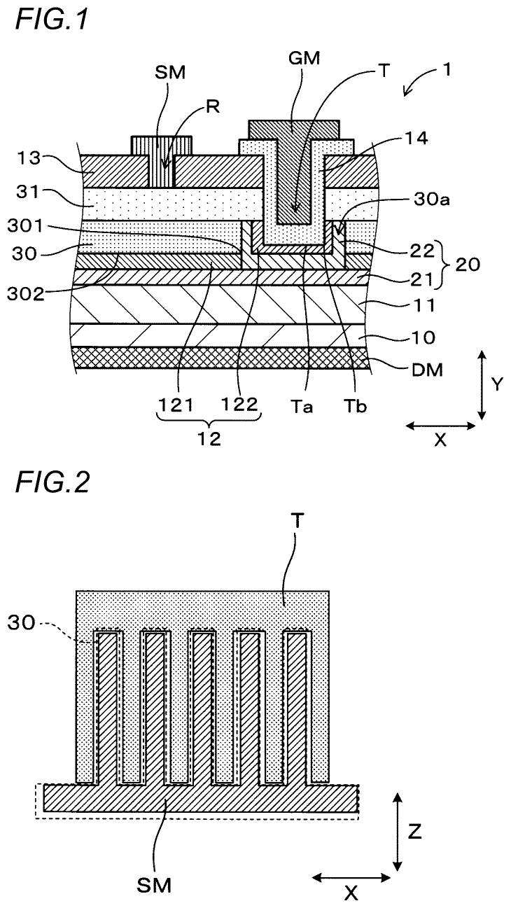

FIG. 1 is a cross-sectional view showing a configuration of a semiconductor device according to a first embodiment, which is a cross-sectional view perpendicular to a substrate main surface. The semiconductor device according to the first embodiment is a MOSFET having a gate trench structure. The semiconductor device according to the first embodiment has a structure in which regular hexagonal unit cells are arranged in a honeycomb shape in a plan view, and has a structure in which the unit cells are connected in parallel.

As shown in FIG. 1, the semiconductor device according to the first embodiment includes a substrate 10, a main drift layer 11, a sub-drift layer 12, a current dispersion layer 20, a second conductivity type blocking layer 30, a second conductivity type body layer 31, a high concentration first conductivity type impurity-containing layer 13, a gate trench T, a recess R, a gate insulating film 14, a gate electrode GM, a source electrode SM, and a drain electrode DM. The gate trench T, the gate insulating film 14, and the gate electrode GM constitute a gate trench structure. All of the gate trench structures are MIS structures.

The substrate 10 is made of a semiconductor containing a first conductivity type impurity, and is made of Si-doped n⁺-GaN having a c plane as a main surface in the present embodiment. A Si concentration in the substrate 10 can be 5×10¹⁷/cm³ to 5× 10²⁰/cm³, and is 2× 10¹⁸/cm³ in the present embodiment. A thickness of the substrate 10 may be 100 μm to 500 μm, and is 300 μm in the present embodiment. A material of the substrate 10 may be a material other than GaN, and any material can be used as long as the material can grow a nitride semiconductor and has conductivity. For example, Si, SiC, or ZnO can be used. However, it is preferable to use a nitride semiconductor, particularly GaN as in the first embodiment.

The main drift layer 11 is provided on the substrate 10 and contains a first conductivity type impurity at a lower concentration than the substrate 10. In the present embodiment, the main drift layer 11 is made of Si-doped n-GaN. A Si concentration in the main drift layer 11 can be 3× 10¹⁵/cm³ to 3×10¹⁶/cm³, and is 1× 10¹⁶/cm³ in the present embodiment. A thickness of the main drift layer 11 can be 0.5 μm to 20 μm, and is 10 μm in the present embodiment.

The current dispersion layer 20 is provided on the main drift layer 11 and contains a first conductivity type impurity at a lower concentration than the substrate 10 and at a higher concentration than the main drift layer 11. In the present embodiment, the current dispersion layer 20 includes a first current dispersion layer 21 and a second current dispersion layer 22.

The first current dispersion layer 21 is formed over an entire upper surface of the main drift layer 11 and is in contact with the main drift layer 11. The first current dispersion layer 21 is made of Si-doped n-GaN. A Si concentration in the first current dispersion layer 21 can be 1×10¹⁶/cm³ to 1× 10¹⁸/cm³, and is 5×10¹⁶/cm³ in the present embodiment. A thickness of the first current dispersion layer 21 can be 0.1 μm to 1.0 μm, and is 0.5 μm in the present embodiment.

The second current dispersion layer 22 covers a wall surface of a groove 30a in the second conductivity type blocking layer 30 to be described later. In the present embodiment, since the groove 30a penetrates a part of a first sub-drift layer 121 and reaches an upper surface of the first current dispersion layer 21, a bottom surface of the second current dispersion layer 22 is in contact with the first current dispersion layer 21. In the present embodiment, the second current dispersion layer 22 is not in contact with a corner portion Tb on a bottom portion Ta of the gate trench T.

The second current dispersion layer 22 is made of Si-doped n-GaN. A Si concentration in the second current dispersion layer 22 is equal to or higher than that of the first current dispersion layer 21, can be 1× 10¹⁶/cm³ to 5×10¹⁸/cm³, and is 1×10¹⁷/cm³ in the present embodiment. A thickness of the second current dispersion layer 22 can be 0.1 μm to 0.6 μm, and is 0.3 μm in the present embodiment.

The sub-drift layer 12 is provided on the current dispersion layer 20 and contains a first conductivity type impurity at a concentration lower than the current dispersion layer 20. In the present embodiment, the sub-drift layer 12 includes the first sub-drift layer 121 and a second sub-drift layer 122.

The first sub-drift layer 121 is in contact with the first current dispersion layer 21 and the second conductivity type blocking layer 30 to be described later, and is formed between the first current dispersion layer 21 and the second conductivity type blocking layer 30 in the present embodiment. In the present embodiment, the first sub-drift layer 121 is made of Si-doped n-GaN. A Si concentration in the first sub-drift layer 121 is lower than the Si concentration in the first current dispersion layer 21, can be 3× 10¹⁵/cm³ to 3× 10¹⁶/cm³, and is 1×10¹⁶/cm³ in the present embodiment. A thickness of the first sub-drift layer 121 can be 0.1 μm to 1.0 μm, and is 0.2 μm in the present embodiment.

The second sub-drift layer 122 is formed to be in contact with the second current dispersion layer 22 and the gate insulating film 14 to be described later, and in the present embodiment, is formed between the second current dispersion layer 22 inside the groove 30a in the second conductivity type blocking layer 30 to be described later and the gate insulating film 14. Accordingly, corner portions Tb on the bottom portion Ta of the gate trench T are all located inside the second sub-drift layer 122. In the present embodiment, the second sub-drift layer 122 is made of Si-doped n-GaN. A Si concentration in the second sub-drift layer 122 is lower than the Si concentration in the second current dispersion layer 22, can be 3× 10¹⁵/cm³ to 3×10¹⁶/cm³, and is 1× 10¹⁶/cm³ in the present embodiment. A thickness of the second sub-drift layer 122 can be 0.1 μm to 1.5 μm, and is 1.0 μm in the present embodiment.

The second conductivity type blocking layer 30 contains a second conductivity type impurity and is provided in contact with the sub-drift layer 12. In the present embodiment, the second conductivity type blocking layer 30 is made of Mg-doped p-GaN and is also referred to as a p blocking layer 30. A Mg concentration in the p blocking layer 30 can be 5×10¹⁷/cm³ to 5×10¹⁹/cm³, and is 1× 10¹⁹/cm³ in the present embodiment. A thickness of the p blocking layer 30 can be 0.3 μm to 1.0 μm, and is 0.5 μm in the present embodiment.

The groove 30a is formed in the second conductivity type blocking layer (p blocking layer) 30. In the present embodiment, the groove 30a includes a bottom region of the gate trench T to be described later inside. In the present embodiment, the groove 30a penetrates a part of the first sub-drift layer 121 provided directly below the p blocking layer 30 and reaches the upper surface of the first current dispersion layer 21. Accordingly, a corner portion 301 of the p blocking layer 30 is located on the wall surface of the groove 30a.

The second conductivity type body layer 31 is provided on the sub-drift layer 12 and the p blocking layer 30. The second conductivity type body layer 31 contains a second conductivity type impurity at a same concentration as the p blocking layer 30 or at a lower concentration than the p blocking layer 30. In the present embodiment, the second conductivity type body layer 31 is made of Mg-doped p-GaN, and is also referred to as a p body layer 31. A Mg concentration in the p body layer 31 can be 1×10¹⁷/cm³ to 4×10¹⁹/cm³, and is 5×10¹⁸/cm³ in the present embodiment. A thickness of the p body layer 31 can be 0.2 μm to 1.0 μm, and is 0.4 μm in the present embodiment.

The high concentration first conductivity type impurity-containing layer 13 is provided on the p body layer 31. The high concentration first conductivity type impurity-containing layer 13 contains a first conductivity type impurity at a higher concentration than the current dispersion layer 20. In the present embodiment, the high concentration first conductivity type impurity-containing layer 13 is made of Si-doped n⁺-GaN and is also referred to as an n-type layer 13. A Si concentration in the n-type layer 13 can be 5×10¹⁷/cm³ to 1×10¹⁹/cm³, and is 2× 10¹⁸/cm³ in the present embodiment. A thickness of the n-type layer 13 can be 0.1 μm to 0.6 μm, and is 0.2 μm in the present embodiment.

The gate trench T has a groove shape extending from the high concentration first conductivity type impurity-containing layer 13 to the sub-drift layer 12. In the present embodiment, the second sub-drift layer 122 is exposed at a bottom surface of the gate trench T. On a side surface of the gate trench T, the second sub-drift layer 122, the p body layer 31, and the n-type layer 13 are exposed in order from a bottom surface side. The p body layer 31 exposed at the side surface of the gate trench T operates as a channel. The bottom portion Ta of the gate trench Tis in contact with the sub-drift layer 12 and is located closer to the n-type layer 13 than a bottom surface 302 of the p blocking layer 30.

A width of the gate trench T can be 0.5 μm to 3 μm, and is 1.5 μm in the present embodiment. A cell pitch can be 3 μm to 10 μm, and is 6 μm in the present embodiment. A trench width can be 0.5 μm to 3 μm, and is 2 μm in the present embodiment. A trench angle is not limited, and is perpendicular to the substrate 10 in the present embodiment.

The recess R is a recessed portion having a depth reaching the p body layer 31 through the n-type layer 13. The recess R is provided to bring the source electrode SM into contact with the p body layer 31.

The gate insulating film 14 is continuously provided in a film shape along the bottom surface, the side surface, and an upper surface of the gate trench T (on the n-type layer 13 near the gate trench T). A material of the gate insulating film 14 is SiO₂, SiN, SiON, Al₂O₃, or the like, and a thickness thereof is, for example, 50 nm.

The gate electrode GM is continuously provided in a film shape along the bottom surface, the side surface, and the upper surface of the gate trench T via the gate insulating film 14. A material of the gate electrode GM is TiN or the like.

The source electrode SM is continuously provided on the p body layer 31 exposed at the bottom surface of the recess R and on the n-type layer 13. A material of the source electrode SM is, for example, Ti/Al, Ti/Al/Ti, V/Al/Ti, or Pd/Al/Ti.

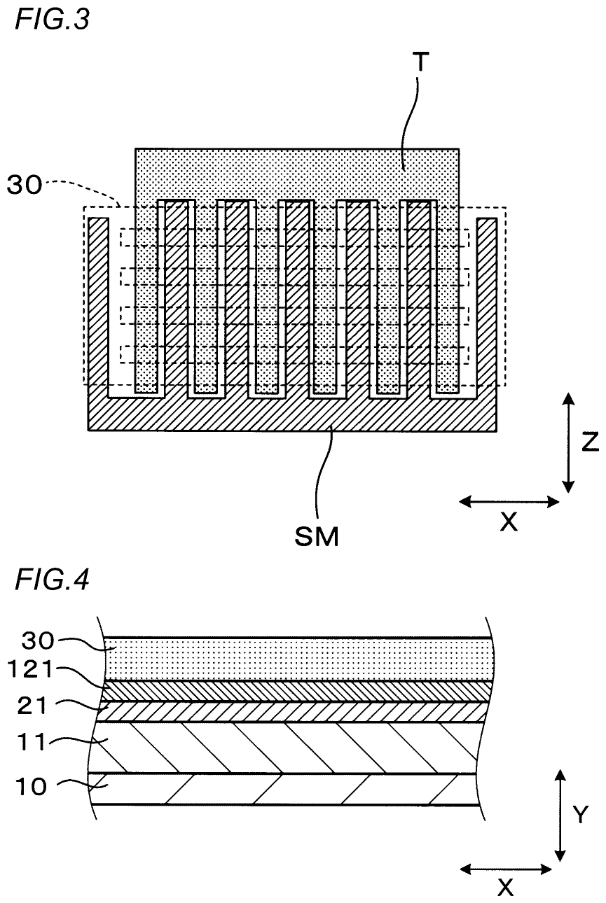

The gate trench T and the source electrode SM are each provided in a predetermined region on a surface of the n-type layer 13. In the present embodiment, as shown in FIG. 2, a plane pattern of the gate trench T and the source electrode SM has a stripe shape in which the gate trench T and the source electrode SM are alternately arranged in parallel. The p blocking layers 30 are provided along the source electrode SM. FIG. 1 corresponds to a cross section in an X direction in FIG. 2. Alternatively, as shown in FIG. 3, the p blocking layers 30 may be provided to intersect the gate trench T and the source electrode SM arranged in a stripe shape.

The drain electrode DM is provided on an entire back surface of the substrate 10. A material of the drain electrode DM is, for example, Ti/Al, Ti/Al/Ti, V/Al/Ti, or Pd/Al/Ti.

### 2. Method for Producing Semiconductor Device

Next, a method for producing a semiconductor device according to the first embodiment will be described with reference to the drawings.

First, as shown in FIG. 4, the main drift layer 11, the first current dispersion layer 21, the first sub-drift layer 121, and the p blocking layer 30 are stacked on the substrate 10 in order from a substrate 10 side. Each layer is formed by using a vapor phase growth method such as an MOCVD method, an HVPE method, an MBE method, or a sputtering method, whereby Si as a first conductivity type impurity or Mg as a second conductivity type impurity has a predetermined doping concentration.

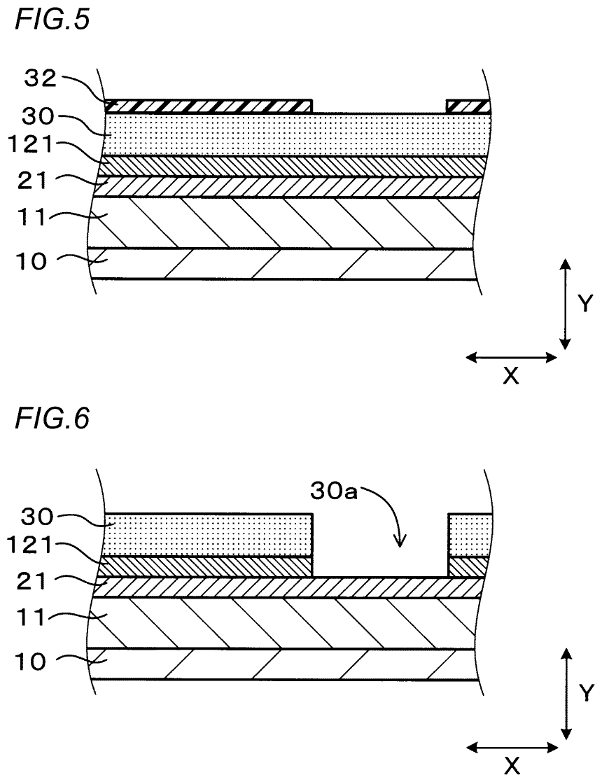

Next, as shown in FIG. 5, a mask pattern 32 is formed on the p blocking layer 30. The mask pattern 32 can be formed of a SiO₂ film. Thereafter, etching is performed to remove the p blocking layer 30 and the first sub-drift layer 121 until the first current dispersion layer 21 is exposed. As shown in FIG. 6, by etching, a region covered with the mask pattern 32 remains, and a region not covered with the mask pattern 32 is removed to form the groove 30a. The etching can be performed by dry etching such as RIE. After the etching, the mask pattern 32 is removed.

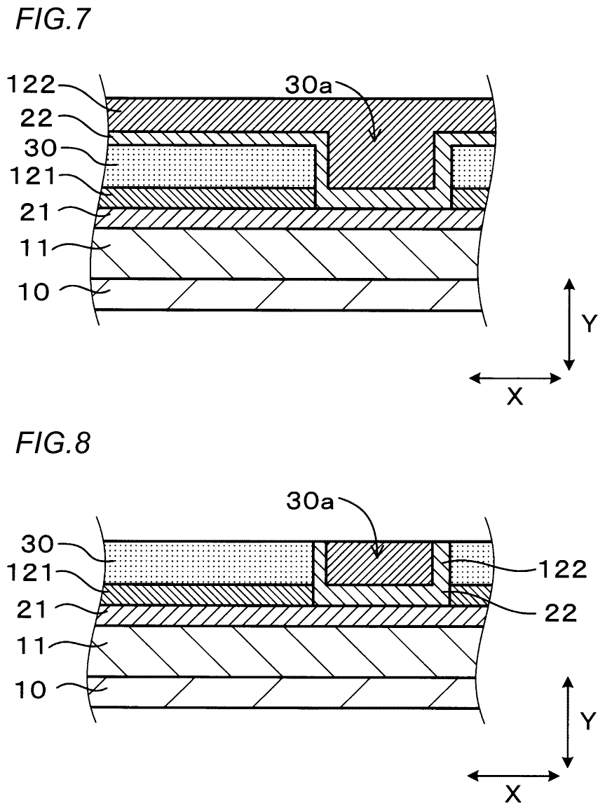

Then, as shown in FIG. 7, the second current dispersion layer 22 and the second sub-drift layer 122 are formed in order on the p blocking layer 30 and the groove 30a. Each layer is formed by using a vapor phase growth method such as an MOCVD method, an HVPE method, an MBE method, or a sputtering method, whereby Si as a first conductivity type impurity has a predetermined doping concentration. Accordingly, the groove 30a is filled with the second current dispersion layer 22 and the second sub-drift layer 122.

Thereafter, as shown in FIG. 8, the second current dispersion layer 22 and the second sub-drift layer 122 are etched until the second current dispersion layer 22 on the p blocking layer 30 disappears and the p blocking layer 30 is exposed. The second current dispersion layer 22 and the second sub-drift layer 122 can be removed by dry etching such as ICE or RIE, wet etching such as PEC, or polishing.

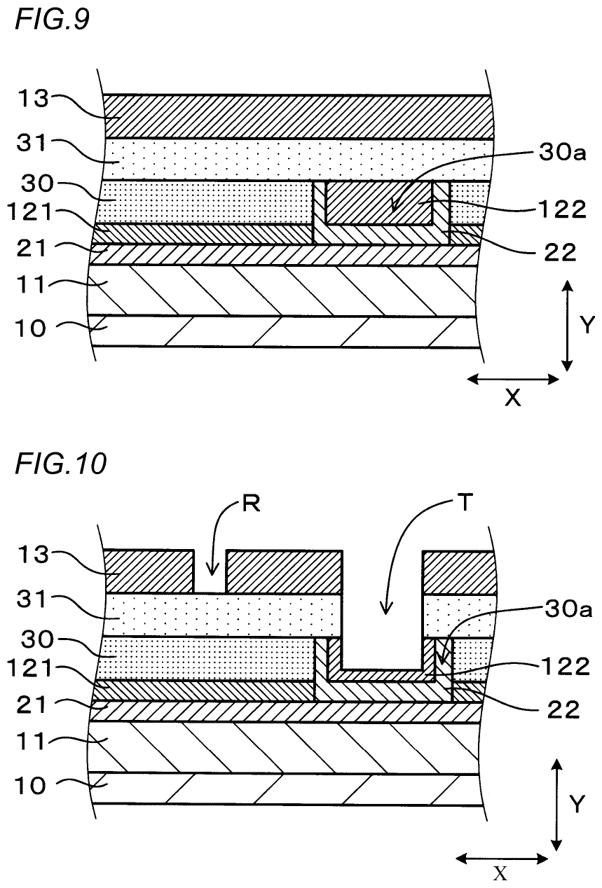

Next, as shown in FIG. 9, the p body layer 31 and the n-type layer 13 (high concentration first conductivity type impurity-containing layer) are formed in order on the p blocking layer 30 and the groove 30a. Each layer is formed by using a vapor phase growth method such as an MOCVD method, an HVPE method, an MBE method, or a sputtering method, whereby Si as a first conductivity type impurity or Mg as a second conductivity type impurity has a predetermined doping concentration.

Next, as shown in FIG. 10, the recess R is formed by dry etching a predetermined region of the n-type layer 13 until the p body layer 31 is exposed, and the gate trench Tis formed by dry etching a predetermined region above the groove 30a in the n-type layer 13, the p body layer 31, and the second sub-drift layer 122. In a region of the gate trench T below the p body layer 31, the wall surface and the bottom portion of the gate trench T are formed in the second sub-drift layer 122.

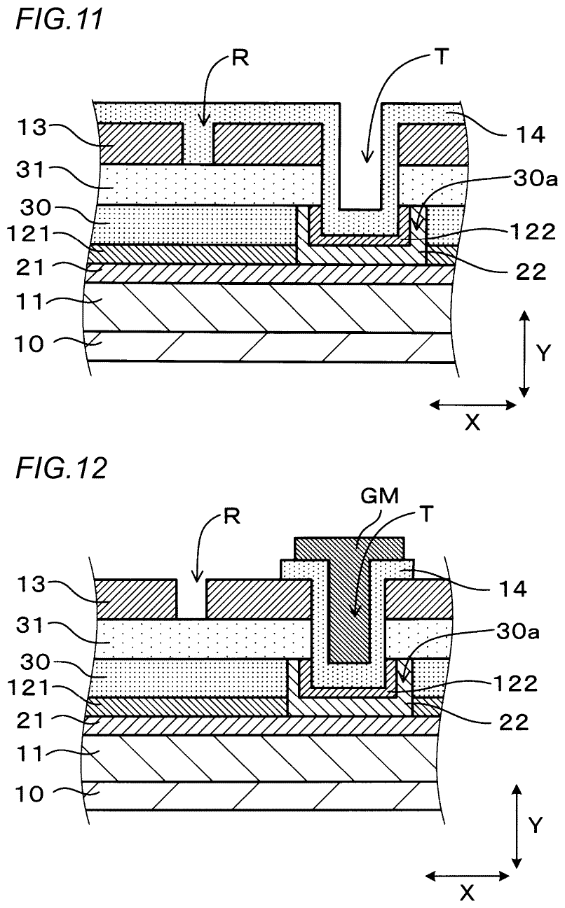

Next, as shown in FIG. 11, the gate insulating film 14 is formed on the entire upper surface of the device. The method of forming the gate insulating film 14 is an ALD method, a CVD method, or the like. In order to form the gate electrode GM on the gate insulating film 14, first, a uniform metal layer having the same stacked structure as the gate electrode GM is formed on the gate insulating film 14, and the uniform metal layer and the gate insulating film 14 are partially removed by etching using a resist or the like. Accordingly, as shown in FIG. 12, the gate electrode GM and the gate insulating film 14 are formed. Next, as shown in FIG. 1, the source electrode SM is continuously formed over the wall surface of the recess R and the surface of the n-type layer 13 in a region near the recess R, and the drain electrode DM is formed on the back surface of the substrate 10. The method of forming the source electrode SM and the drain electrode DM is vapor deposition or the like.

### 3. Operations and Effects

According to the semiconductor device 1 of the present embodiment, the sub-drift layer 12 is provided on the current dispersion layer 20 formed on the main drift layer 11, and the p blocking layer 30 having the groove 30a is provided in contact with the sub-drift layer 12. Then, the gate trench T is formed in a groove shape reaching at least the sub-drift layer 12, and the bottom portion Ta of the gate trench T is located closer to the n-type layer 13 than the bottom surface 302 of the p blocking layer 30. Accordingly, since a wide current flow path in the current dispersion layer 20 can be ensured, it is possible to make it easier for a large amount of current to flow in the on-state and to reduce the on-resistance. Further, with the above configuration, the p blocking layer 30 can prevent an increase in electric field strength at the corner portion on the bottom portion Ta of the gate trench T or the corner portion 301 of the p blocking layer 30 on a trench side, and a leakage current is less likely to flow, thereby improving a breakdown voltage. Therefore, it is possible to achieve both an improvement in breakdown voltage and a reduction in on-resistance.

In the first embodiment, the current dispersion layer 20 includes the first current dispersion layer 21 in contact with the main drift layer 11 and the second current dispersion layer 22 covering the wall surface of the groove 30a of the p blocking layer 30. The sub-drift layer 12 includes the first sub-drift layer 121 in contact with the first current dispersion layer 21 and the p blocking layer 30, and the second sub-drift layer 122 in contact with the second current dispersion layer 22 and the gate insulating film 14. Accordingly, while the on-resistance is further reduced by the second current dispersion layer 22, the generation of the leakage current can be further prevented by the first sub-drift layer 121, the second sub-drift layer 122, the first current dispersion layer 21, and the second current dispersion layer 22 to improve the breakdown voltage.

In the first embodiment, the second current dispersion layer 22 is not in contact with the corner portion Tb on the bottom portion Ta of the gate trench T. Accordingly, an increase in electric field strength at the corner portion Tb on the bottom portion Ta of the gate trench T can be prevented to improve the breakdown voltage.

In the first embodiment, the first current dispersion layer 21 and the second current dispersion layer 22 are in contact with each other. Accordingly, the current dispersion effect is promoted, and the on-resistance can be further reduced.

In the first embodiment, the bottom portion Ta of the gate trench T enters the groove 30a of the p blocking layer 30, and the second sub-drift layer 122 is interposed between the bottom portion Ta of the gate trench T and the second current dispersion layer 22. Accordingly, the generation of the leakage current can be prevented to improve the breakdown voltage.

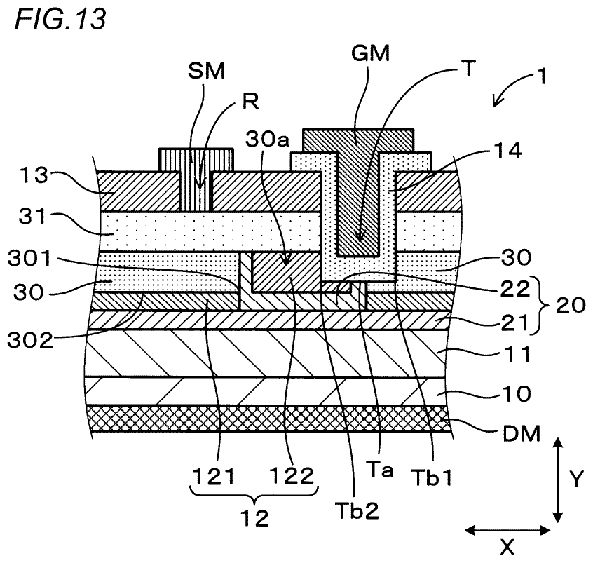

In the first embodiment, all of the corner portions Tb on the bottom portion Ta of the gate trench T are located inside the second sub-drift layer 122. Alternatively, as in a first modification shown in FIG. 13, the bottom portion Ta of the gate trench T may include a portion Tb2 entering the groove 30a of the p blocking layer 30 and a portion Tb1 located inside the p blocking layer 30, and the corner portions Tb1 and Tb2 on the bottom portion Ta of the gate trench T may not be in contact with the second current dispersion layer 22. According to the first modification, similar to the case of the first embodiment, the generation of the leakage current can be prevented to improve the breakdown voltage.

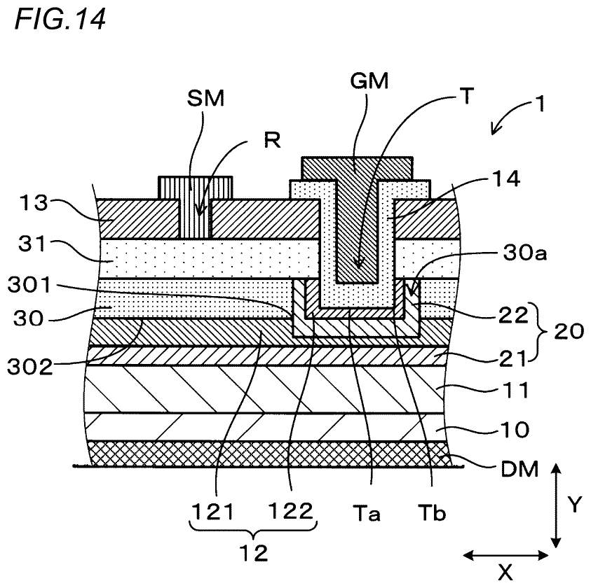

In the first embodiment, a bottom portion of the second current dispersion layer 22 is in contact with the first current dispersion layer 21. Alternatively, as in a second modification shown in FIG. 14, the first sub-drift layer 121 may be interposed between the first current dispersion layer 21 and the second current dispersion layer 22. As in the second modification, even when the first current dispersion layer 21 and the second current dispersion layer 22 are separated from each other, the effect of reducing the on-resistance can be obtained, and the generation of the leakage current can be prevented to improve the breakdown voltage.

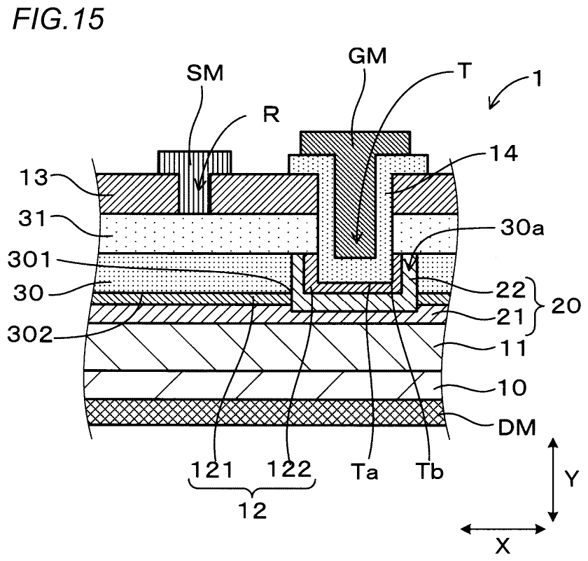

As in a third modification shown in FIG. 15, a portion of the second current dispersion layer 22 may enter the first current dispersion layer 21. According to the third modification, since a contact area between the first current dispersion layer 21 and the second current dispersion layer 22 increases, the current dispersion effect can be promoted to further reduce the on-resistance, and the generation of the leakage current can be prevented to improve the breakdown voltage.

As described above, in the first embodiment and the first modification to the third modification, it is possible to provide a semiconductor device 1 capable of achieving both an improvement in breakdown voltage and a reduction in on-resistance.

### Second Embodiment

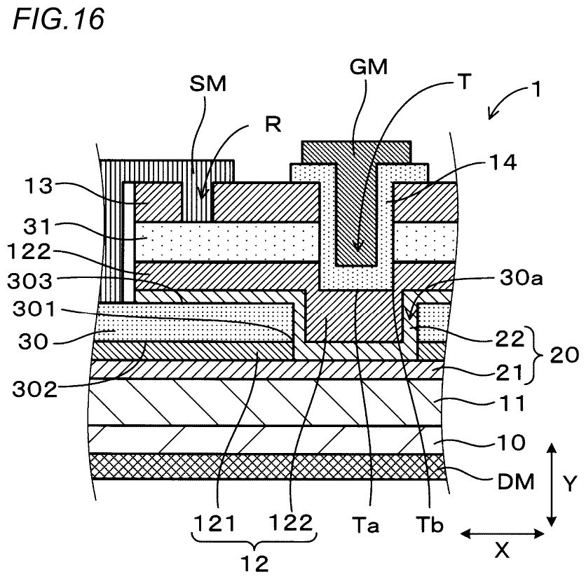

In the first embodiment described above, as shown in FIG. 1, the second current dispersion layer 22 and the second sub-drift layer 122 are provided only in the groove 30a of the p blocking layer 30. Alternatively, in the semiconductor device 1 according to the second embodiment, as shown in FIG. 16, the second current dispersion layer 22 and the second sub-drift layer 122 are provided in the groove 30a of the p blocking layer 30 and over an entire upper surface 303 of the p blocking layer 30. Similar to the case of the first embodiment, the entire bottom portion Ta of the gate trench T is located inside the second sub-drift layer 122.

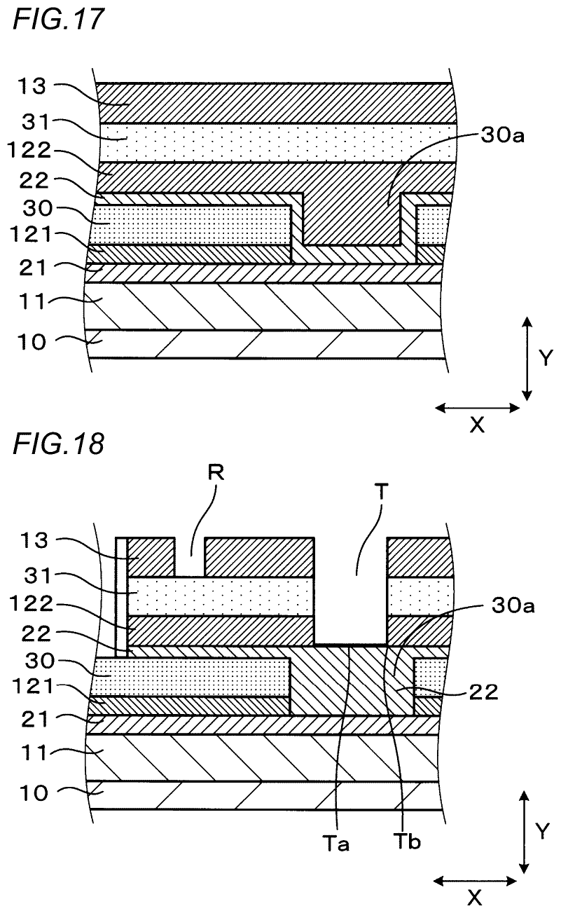

In a method for producing the semiconductor device 1 according to the second embodiment, similar to the case of the first embodiment, the second sub-drift layer 122 is formed as shown in FIG. 7, then the second current dispersion layer 22 and the second sub-drift layer 122 are not removed, and subsequently, as shown in FIG. 17, the p body layer 31 and the n-type layer 13 are formed in order on the second sub-drift layer 122. Each layer is formed by using a vapor phase growth method such as an MOCVD method, an HVPE method, an MBE method, or a sputtering method, whereby Si as a first conductivity type impurity or Mg as a second conductivity type impurity has a predetermined doping concentration. Since epitaxial growth from the second current dispersion layer 22 to the n-type layer 13 can be performed at once by using the MOCVD method, there is an advantage that the number of steps can be reduced.

As shown in FIG. 18, the recess R is formed by dry etching a predetermined region of the n-type layer 13 until the p body layer 31 is exposed, and the gate trench Tis formed by dry etching a predetermined region above the groove 30a in the n-type layer 13, the p body layer 31, and the second sub-drift layer 122 until the second current dispersion layer 22 is exposed. Accordingly, the groove 30a is filled with the second current dispersion layer 22.

Thereafter, similar to the case of the first embodiment, the gate insulating film 14 and the gate electrode GM are formed, the source electrode SM is continuously formed over the wall surface of the recess R and the surface of the n-type layer 13 in a region near the recess R, and the drain electrode DM is formed on the back surface of the substrate 10 (see FIG. 16). The method of forming the source electrode SM and the drain electrode DM is vapor deposition or the like.

According to the second embodiment, the second sub-drift layer 122 is in contact with the entire lower surface of the p body layer 31, and the second current dispersion layer 22 is in contact with an entire lower surface of the second sub-drift layer 122. Accordingly, the current dispersion effect is promoted, and the on-resistance can be further reduced.

The second embodiment has the same effects as the first embodiment. Further, in the second embodiment, when the p blocking layer 30 and the p body layer 31 are connected to each other to have the same potential, the p blocking layer 30 can further prevent an increase in electric field strength of the corner portion on the bottom portion Ta of the gate trench T or the corner portion 301 of the p blocking layer 30 on the trench side, and the breakdown voltage can be further improved.

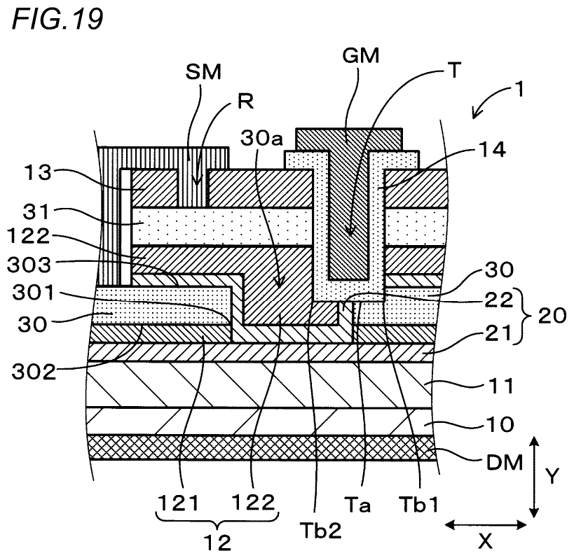

In the second embodiment, the entire bottom portion Ta of the gate trench T is located inside the second sub-drift layer 122. Alternatively, as in a fourth modification shown in FIG. 19, the bottom portion Ta of the gate trench T may include the portion Tb2 entering the groove 30a of the p blocking layer 30 and the portion Tb1 located inside the p blocking layer 30, and the corner portions Tb1 and Tb2 on the bottom portion Ta of the gate trench T may not be in contact with the second current dispersion layer 22. According to the fourth modification, similar to the case of the second embodiment, the generation of the leakage current can be prevented to improve the breakdown voltage.

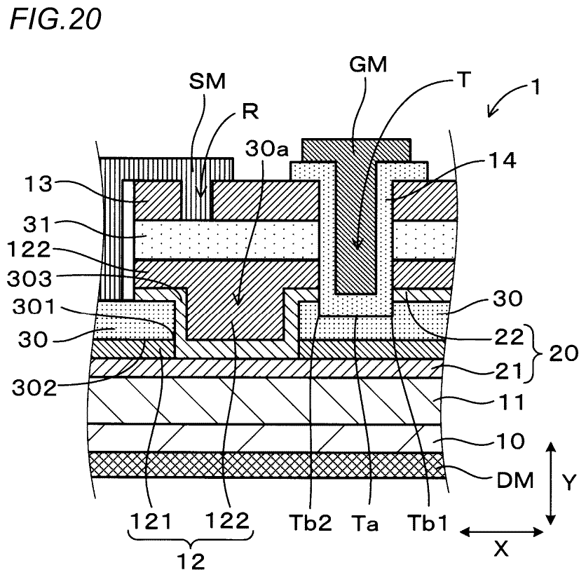

As in a fifth modification shown in FIG. 20, the entire bottom portion Ta of the gate trench T may be located inside the p blocking layer 30, and the corner portions Tb1 and Tb2 on the bottom portion Ta of the gate trench T may not be in contact with the second current dispersion layer 22. According to the fifth modification, similar to the case of the second embodiment, the generation of the leakage current can be prevented to improve the breakdown voltage.

The first conductivity type impurity is of n type and the second conductivity type impurity is of p type in the first embodiment, the second embodiment, and the first modification to the fifth modification. Alternatively, the first conductivity type impurity may be of p type and the second conductivity type impurity may be of n type.

### REFERENCE SIGNS LIST

1: semiconductor device
10: substrate
11: main drift layer
12: sub-drift layer
121: first sub-drift layer
122: second sub-drift layer
13: high concentration first conductivity type impurity-containing layer (n-type layer)
14: gate insulating film
20: current dispersion layer
21: first current dispersion layer
22: second current dispersion layer
30: second conductivity type blocking layer (p blocking layer)
30a: groove
301: corner portion
302: bottom surface
303: upper surface
31: second conductivity type body layer (p body layer)
32: mask pattern
DM: drain electrode
GM: gate electrode
R: recess
SM: source electrode
T: gate trench

What is claimed is:

1. A semiconductor device comprising:
a substrate comprising a semiconductor containing a first conductivity type impurity;
a main drift layer provided over the substrate and containing a first conductivity type impurity at a lower concentration than a concentration of the first conductivity type impurity in the substrate;
a current dispersion layer provided over the main drift layer and containing a first conductivity type impurity at a lower concentration than the concentration of the first conductivity type impurity in the substrate and at a higher concentration than the concentration of the first conductivity type impurity in the main drift layer;
a sub-drift layer provided over the current dispersion layer and containing a first conductivity type impurity at a lower concentration than the concentration of the first conductivity type impurity in the current dispersion layer;
a second conductivity type blocking layer containing a second conductivity type impurity, provided in contact with the sub-drift layer, and having a groove;
a second conductivity type body layer provided over the sub-drift layer and the second conductivity type blocking layer, and containing a second conductivity type impurity at a same concentration as a concentration of the second conductivity type impurity in the second conductivity type blocking layer or at a lower concentration than the concentration of the second conductivity type impurity in the second conductivity type blocking layer;
a high concentration first conductivity type impurity-containing layer provided over the second conductivity type body layer and containing a first conductivity type impurity at a higher concentration than the concentration of the first conductivity type impurity in the current dispersion layer;
a gate trench formed in a groove shape extending from the high concentration first conductivity type impurity-containing layer to at least the sub-drift layer;
a gate insulating film provided in a film shape along a bottom surface and a side surface of the gate trench; and
a gate electrode provided in a film shape along the bottom surface and the side surface of the gate trench via the gate insulating film, wherein
a bottom portion of the gate trench is located closer to the high concentration first conductivity type impurity-containing layer than a bottom surface of the second conductivity type blocking layer.

2. The semiconductor device according to claim 1, wherein
the current dispersion layer includes a first current dispersion layer in contact with the main drift layer, and a second current dispersion layer covering a wall surface of the groove of the second conductivity type blocking layer, and
the sub-drift layer includes a first sub-drift layer in contact with the first current dispersion layer and the second conductivity type blocking layer, and a second sub-drift layer in contact with the second current dispersion layer and the gate insulating film.

3. The semiconductor device according to claim 2, wherein the second current dispersion layer is disposed so as not to be in contact with a corner portion on the bottom portion of the gate trench.

4. The semiconductor device according to claim 3, wherein the first current dispersion layer and the second current dispersion layer are in contact with each other.

5. The semiconductor device according to claim 2, wherein
the second sub-drift layer is in contact with an entire lower surface of the second conductivity type body layer, and
the second current dispersion layer is in contact with an entire lower surface of the second sub-drift layer.

6. The semiconductor device according to claim 3, wherein the first sub-drift layer is interposed between the first current dispersion layer and the second current dispersion layer.

7. The semiconductor device according to claim 3, wherein a portion of the second current dispersion layer enters the first current dispersion layer.

8. The semiconductor device according to claim 2, wherein
the bottom portion of the gate trench enters the groove of the second conductivity type blocking layer, and
the second sub-drift layer is interposed between the bottom portion of the gate trench and the second current dispersion layer.

9. The semiconductor device according to claim 2, wherein the bottom portion of the gate trench includes a portion entering the groove of the second conductivity type blocking layer and a portion located inside the second conductivity type blocking layer, and a corner portion on the bottom portion of the gate trench is not in contact with the second current dispersion layer.

10. The semiconductor device according to claim 2, wherein an entire part of the bottom portion of the gate trench is located inside the second conductivity type blocking layer, and a corner portion on the bottom portion of the gate trench is not in contact with the second current dispersion layer.
